(19) United States
(12) Patent Application Publication
(10) Pub. No.: US 2017/0284267 A1
(43) Pub. Date: Oct. 5, 2017

(54) EXHAUST MANIFOLD FOR VEHICLE

(71) Applicant: Hyundai Motor Company, Seoul (KR)

(72) Inventors: Jin Woo KWAK, Gyeongsan-si (KR); In Woong LYO, Suwon-si (KR); Ji Ho KIM, Seoul (KR); Min Kyu PARK, Yongin-si (KR); Kyong Hwa SONG, Seoul (KR); Seung Woo LEE, Seoul (KR); Han Saem LEE, Seoul (KR); Hong Kil BAEK, Seoul (KR); Byung Wook KIM, Seongnam-si (KR); Kwang Hee NAM, Ansan-si (KR); Sang Soo MIN, Bucheon-si (KR)

(73) Assignee: Hyundai Motor Company, Seoul (KR)

(21) Appl. No.: 15/365,379

(22) Filed: Nov. 30, 2016

(30) Foreign Application Priority Data
Mar. 29, 2016 (KR) 10-2016-0037940

(51) Int. Cl. F01N 5/02; H01L 35/08; H01L 35/30; F01N 13/10

(52) U.S. Cl. CPC F01N 5/025; F01N 13/10; H01L 35/08; H01L 35/30; F01N 3/10

(57) ABSTRACT

An exhaust manifold for a vehicle configured for improving fuel efficiency of the vehicle by improving fluidity of exhaust gas may include a manifold body having a plurality of inlet portions which are outwardly extended and an outlet portion which is outwardly extended, wherein the manifold body may have a flat surface formed on at least a portion of a top surface thereof.

### CROSS-REFERENCE TO RELATED APPLICATION

The present application is based on and claims the benefit of priority to Korean Patent Application No. 10-2016-0037940, filed on Mar. 29, 2016 in the Korean Intellectual Property Office, the entire contents of which is incorporated herein for all purposes by this reference.

### FIELD OF THE INVENTION

The present invention relates to an exhaust manifold for a vehicle, and more particularly, to an exhaust manifold for a vehicle configured for improving fuel efficiency of the vehicle by improving fluidity of exhaust gas.

### BACKGROUND

An exhaust manifold is mounted in an engine to collect exhaust gas generated from a combustion chamber of the engine and to discharge the collected exhaust gas to the outside of the engine, and a catalyst purifying the exhaust gas may be connected to a downstream of the exhaust manifold.

Fluidity of the exhaust gas discharged through the exhaust manifold is greatly influenced by factors such as a flow uniformity index, a velocity index, a tangential speed, a pressure drop, and the like, and is predictable.

Here, the flow uniformity index is a quantitative numerical value showing how uniformly the exhaust gas flows in the entire area of the catalyst (the flow uniformity index becomes close to ‘1’ when the same flow rate per a unit time contacts the entire area of the catalyst), the velocity index is a quantitative numerical value showing how much the exhaust gas is eccentric from a center of the catalyst when the exhaust gas is transferred to the catalyst (the velocity index becomes close to ‘1’ as the exhaust gas is eccentric from the center of the catalyst), the tangential speed is a speed when the exhaust gas passes over a ceramic mat surrounding the catalyst, and the pressure drop, which is pressure acting on the flow of the exhaust gas, is a factor that directly influences the engine and is preferably maintained to be low.

Meanwhile, due to structural and shape limits of the exhaust manifold according the related art, there are disadvantages in that it is difficult to improve fluidity of the exhaust gas and it is difficult to stably mount an exhaust heat collection mechanism such as a thermoelectric module, or the like due to a complex curved structure.

The information disclosed in this Background of the Invention section is only for enhancement of understanding of the general background of the invention and should not be taken as an acknowledgement or any form of suggestion that this information forms the prior art already known to a person skilled in the art.

### BRIEF SUMMARY

Various aspects of the present invention are directed to providing an exhaust manifold for a vehicle configured for improving fluidity of exhaust gas by improving a flow uniformity index, a velocity index, a tangential speed, a pressure drop, and the like, and improving fuel efficiency of the vehicle by the improvement of the fluidity of the exhaust gas.

According to an exemplary embodiment of the present invention, an exhaust manifold for a vehicle includes a manifold body having a plurality of inlet portions which are outwardly extended and an outlet portion which is outwardly extended, wherein the manifold body may have a flat surface formed on at least a portion of a top surface thereof.

A volume of the manifold body may be formed to be greater than that of the inlet portions.

At least one stud may protrude from the flat surface of the manifold body.

An inlet flange may be coupled to the plurality of inlet portions, and the inlet flange may have a plurality of openings which are in communication with the plurality of inlet portions.

A catalyst converter may be connected to the outlet portion.

According to another exemplary embodiment of the present invention, an exhaust manifold for a vehicle includes a manifold body having a flat surface formed on at least a portion of a top surface thereof; and an exhaust heat collection mechanism configured to be mounted onto the flat surface of the manifold body.

The exhaust heat collection mechanism may include at least one thermoelectric module.

A stud for mounting the exhaust heat collection mechanism may protrude from the flat surface of the manifold body.

A heat protect cover may be coupled to a top surface of the manifold body using the stud.

A cooling jacket may be mounted on the thermoelectric modules.

The exhaust manifold may further include a pressurizing member configured to pressurize the thermoelectric modules toward the flat surface of the manifold body.

The pressurizing member may be configured of a pressurizing mat mounted on the cooling jacket.

The pressurizing member may be comprised of a metal mesh having both damping property and pressurizing property.

A heat protect cover covering the thermoelectric modules may be mounted on the manifold body using the stud.

A pressurizing plate pressurizing the pressurizing member may be mounted on the pressurizing member.

An insulation may be filled around the thermoelectric modules.

The methods and apparatuses of the present invention have other features and advantages which will be apparent from or are set forth in more detail in the accompanying drawings, which are incorporated herein, and the following Detailed Description, which together serve to explain certain principles of the present invention.

### BRIEF DESCRIPTION OF THE DRAWINGS

FIG. 1 is a perspective view illustrating an exhaust manifold for a vehicle and a catalyst converter connected thereto, according to an exemplary embodiment of the present invention.

FIG. 2 is a side view illustrating the exhaust manifold for a vehicle according to an exemplary embodiment of the present invention.

FIG. 3 is a plan view when being viewed from a direction of an arrow A of FIG. 2.

FIG. 4 is a view illustrating a state in which a thermoelectric module is mounted onto the exhaust manifold for a vehicle of FIG. 3.

FIG. 5 is a partial cross-sectional view illustrating an example in which the thermoelectric module is mounted onto the exhaust manifold for a vehicle according to an exemplary embodiment of the present invention.

FIG. 6 is a partial cross-sectional view illustrating another example in which the thermoelectric module is mounted onto the exhaust manifold for a vehicle according to an exemplary embodiment of the present invention.

It should be understood that the appended drawings are not necessarily to scale, presenting a somewhat simplified representation of various features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Reference will now be made in detail to various embodiments of the present invention(s), examples of which are illustrated in the accompanying drawings and described below. While the invention(s) will be described in conjunction with exemplary embodiments, it will be understood that the present description is not intended to limit the invention(s) to those exemplary embodiments. On the contrary, the invention(s) is/are intended to cover not only the exemplary embodiments, but also various alternatives, modifications, equivalents and other embodiments, which may be included within the spirit and scope of the invention as defined by the appended claims.

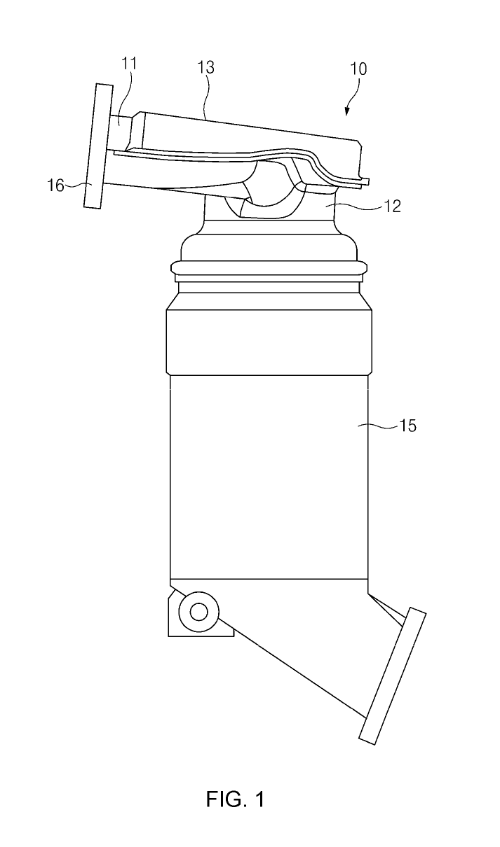

Referring to FIG. 1, an exhaust manifold for a vehicle according to various exemplary embodiments of the present invention may include a manifold body 10.

A plurality of inlet portions 11 are outwardly extended from a first side of the manifold body 10 and are coupled to an engine side, such that exhaust gas generated from an engine may be introduced into the manifold body 10 through the plurality of inlet portions 11.

An inlet flange 16 may be coupled to the plurality of inlet portions 11, and may have a plurality of openings which are in communication with the plurality of inlet portions 11.

An outlet portion 12 is formed at a second side of the manifold body 10, and may be connected to a catalyst converter 15, an exhaust pipe, or the like.

An internal space may be formed in the manifold body 10, and the exhaust gas introduced through the plurality of the inlet portions 11 is collected in the internal space.

The manifold body 10 may have a flat surface 13 formed on at least one surface thereof, and FIGS. 1 to 3 illustrate that the flat surface 13 is formed on a top surface of the manifold body 10.

As the flat surface 13 is formed on at least one surface of the manifold body 10, a volume of the manifold body 10 may be formed to be greater than that of each of the inlet portions 11. Accordingly, as a cross-sectional area of the manifold body 10 is formed to be greater than that of the inlet portions, a pressure drop is decreased, making it possible to improve fluidity of the exhaust gas.

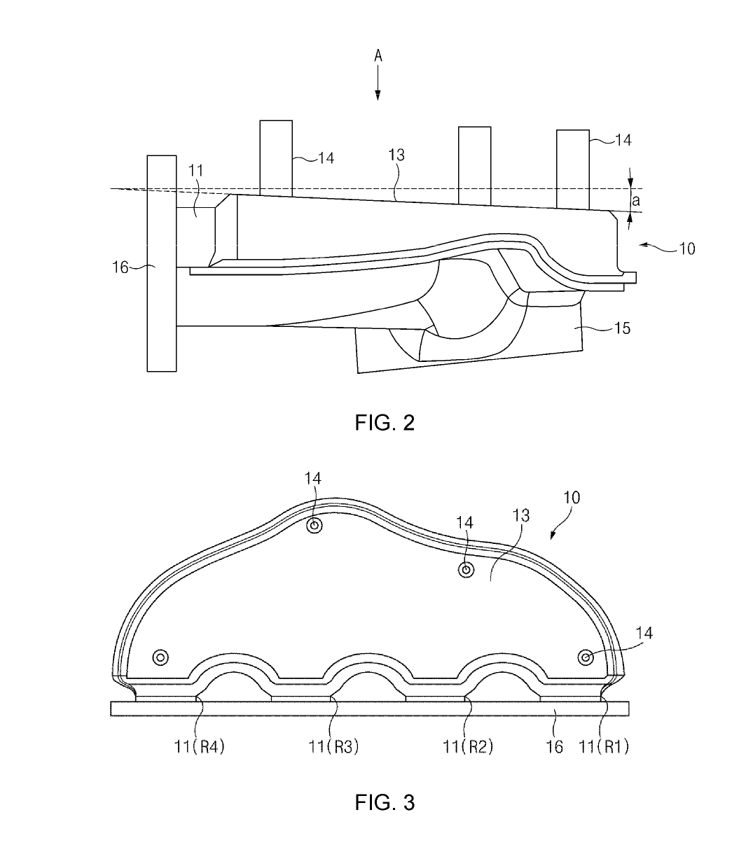

In addition, the flat surface 13 is positioned to be inclined at a predetermined angle (a) from a horizontal surface as illustrated in FIG. 2, making it possible to more smoothly implement a flow of the exhaust gas.

The following Table 1 is a result table obtained by comparing a flow uniformity index, a velocity index, a tangential speed, a pressure drop, and the like between the exhaust manifold according to an exemplary embodiment of the present invention and a comparative example (an exhaust manifold according to the related art).

TABLE 1

| | | | | | Exemplary Embodiment | | | |
|---|---|---|---|---|---|---|---|---|
| | Comparative Example | | | | of the Present invention | | | |
| | R1 | R2 | R3 | R4 | R1 | R2 | R3 | R4 |
| Flow Uniformity | 0.97 | 0.92 | 0.95 | 0.97 | 0.97 | 0.96 | 0.97 | 0.97 |
| Index (UI) | | | | | | | | |
| Velocity Index (VI) | 0.83 | 0.83 | 0.81 | 0.82 | 0.87 | 0.84 | 0.87 | 0.79 |
| Tangential Speed | 114.5 | 166.3 | 160.6 | 97.25 | 107.7 | 118.1 | 140.2 | 122.1 |
| (T/S, m/s) | | | | | | | | |
| ΔP_1 (kPa) | 22.29 | 18.8 | 19.7 | 21.83 | 20.06 | 15.77 | 16.33 | 21.77 |
| ΔP_2 (kPa) | 24.4 | 25.79 | 25.37 | 23.17 | 23.42 | 23.93 | 24.19 | 23.39 |
| ΔP_3 (kPa) | 0.63 | 0.74 | 0.62 | 0.68 | 0.69 | 0.73 | 0.67 | 0.67 |
| ΔP_Total (kPa) | 47.32 | 45.33 | 45.69 | 45.68 | 44.17 | 40.43 | 41.19 | 45.83 |

The exhaust manifold according to the comparative example and the exemplary embodiment of the present invention of Table 1 described above has four inlet portions such as R1, R2, R3, and R4.

In addition, ΔP_1 denotes the pressure drop of the exhaust gas acting when the exhaust gas passes through the manifold body 11 and the outlet portion 12 through each of the inlet portions R1, R2, R3, and R4 of the exhaust manifold, ΔP_2 denotes the pressure drop of the exhaust gas acting when the exhaust gas introduced into each of the inlet portions R1, R2, R3, and R4 passes through the catalyst converter 15, ΔP_3 denotes the pressure drop of the exhaust gas acting when the exhaust gas introduced into each of the inlet portions R1, R2, R3, and R4 passes through a downstream of the catalyst converter 15, and ΔP_Total denotes a total of the pressure drop acting when the exhaust gas introduced into each of the inlet portions R1, R2, R3, and R4 passes through the catalyst converter from the exhaust manifold.

As can be seen from Table 1 described above, it may be seen that the flow uniformity index (UI) is improved as much as about 1.6% in the exemplary embodiment of the present invention as compared to the related art, it may be seen that the tangential speed (T/S) is improved as much as about 9.4% in the exemplary embodiment of the present invention as compared to the related art, and it may be seen that the pressure drop is improved as much as about 6.7% in the exemplary embodiment of the present invention as compared to the related art.

Accordingly, according to an exemplary embodiment of the present invention, it may be seen that as the flow uniformity index (UI), the tangential speed (T/S), the pressure drop, and the like are improved, the fluidity of the exhaust gas is improved as compared to the related art.

In addition, a plurality of studs 14 may be formed on the flat surface 13 of the manifold body 10 to upwardly protrude from the flat surface 13. The studs 14 may be fixed to the flat surface 13 of the manifold body 10 by welding, or the like.

According to various exemplary embodiments of the present invention, an exhaust heat collection mechanism, a variety of components, or the like such as a thermoelectric module 20 may be mounted onto the flat surface 13 of the manifold body 10.

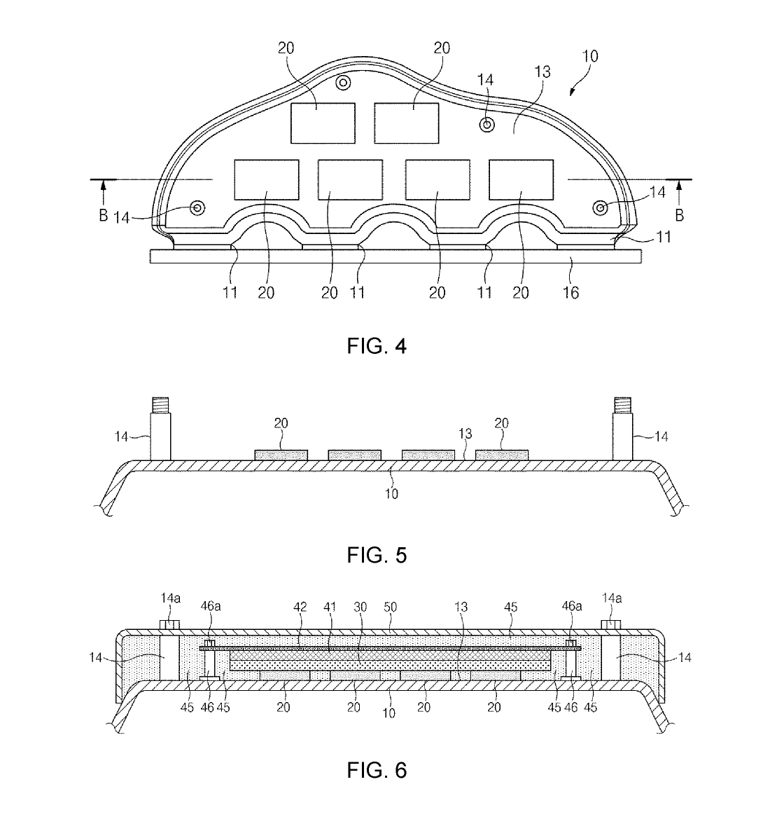

As illustrated in FIG. 4 and FIG. 5, the thermoelectric module 20 may be very easily and firmly mounted onto the flat surface 13 of the manifold body 10. For example, according to the various exemplary embodiments of the present invention, as the flat surface 13 is formed on at least one surface of the manifold body 10, the thermoelectric module 20 may be very firmly and stably mounted onto the exhaust manifold, making it possible to improve generation efficiency of the thermoelectric module 20.

The thermoelectric module 20 may be formed in various structures having a semiconductor part having a pair of semiconductor elements (a p-type semiconductor element and a n-type semiconductor element) of which polarities are opposite to each other, an upper electrode connected to an upper portion of the semiconductor part, a lower electrode connected to a lower portion of the semiconductor part, an upper substrate supporting the upper electrode, and a lower substrate supporting the lower electrode.

As illustrated in FIG. 5, a bottom surface of the thermoelectric module 20 is mounted on the flat surface 13 of the manifold body 10. Accordingly, since a lower portion of the thermoelectric module 20 receives exhaust heat of the exhaust gas, the lower portion of the thermoelectric module 20 may be configured as a high temperature portion.

A cooling jacket 30 is mounted on an upper portion of the thermoelectric module 20. Accordingly, since the cooling jacket 30 cools the upper portion of the thermoelectric module 20, the upper portion of the thermoelectric module 20 may be configured as a low temperature portion. The cooling jacket 30 may have a cooling passage through which a cooling medium passes.

Accordingly, since the lower portion of the thermoelectric module 20 is configured as the high temperature portion by the manifold body 10, and the upper portion of the thermoelectric module 20 is configured as the low temperature portion by the cooling jacket 30, the thermoelectric module 20 may perform thermoelectric generation using a temperature difference between the high temperature portion and the low temperature portion.

In addition, according to the various exemplary embodiments of the present invention, the exhaust manifold may further include a pressurizing member 41 pressurizing the thermoelectric module 20 toward the flat surface 13 of the manifold body 10, as illustrated in FIG. 6.

According to an exemplary embodiment, the pressurizing member 41 may be configured of a pressurizing mat mounted on the cooling jacket 30. The pressurizing mat may be formed in a structure in which a ceramic fiber and a layered silicate material are mixed to have a predetermined compression ratio. Surface pressure of the pressurizing mat 31 is adjusted depending on the compression ratio of the pressurizing mat 31, making it possible to secure appropriate pressurizing performance for the thermoelectric module 20.

The thermoelectric module 20 and the cooling jacket 30 may be more firmly mounted at the manifold body 10 side by the pressurizing member 41, making it possible to prevent the thermoelectric module 20 from being damaged by vibration or the like. In addition, the thermoelectric module 20 is closely adhered to the flat surface 13 of the manifold body 10 by the pressurizing member 41, making it possible to maintain firm mounting property of the cooling jacket 30 and the thermoelectric module 20.

According to another exemplary embodiment, the pressurizing member 41 may be comprised of a metal mesh having both damping property and pressurizing property. The metal mesh may have a predetermined compression ratio similarly to the pressurizing mat described above, and surface pressure of the metal mesh is adjusted depending on the compression ratio of the metal mesh, making it possible to secure appropriate pressurizing performance for the thermoelectric modules 20.

Further, since the metal mesh may have the damping property, the metal mesh may perform an damping configured for a thermal expansion of the thermoelectric module 20, making it possible to also prevent damage to the thermoelectric modules 20.

In addition, a heat protect cover 50 covering a side surface and a top surface of the thermoelectric module 20 may be mounted on the manifold body 10 using the studs 14.

As fasteners 14a including a nut, and the like are fastened to upper ends of the studs 14, the heat protect cover 50 may be mounted to cover the upper portion and the side surface of the thermoelectric module 20. Accordingly, since the heat protect cover 50 covers the upper portion and the side surface of the thermoelectric module 20, it is possible to prevent heat of the exhaust gas from being disappeared to an outside as well as it is possible to stably protect the thermoelectric module 20, from an external physical influence.

A pressurizing plate 42 pressurizing the pressurizing member 41 may be mounted on the pressurizing member 41, and may be mounted using auxiliary studs 46.

After the pressurizing plate 42 is seated on upper ends of the auxiliary studs 46, as fasteners 46a such as a nut, or the like are fastened to threaded portions of the upper ends of the auxiliary studs 46, the pressurizing plate 42 may be mounted on a top surface of the pressurizing member 41.

In addition, an insulation 45 such as a glass wool, or the like may be densely filled around the thermoelectric module 20. Accordingly, it is possible to prevent a variety of f components of the thermoelectric module 20 from being separated to an outside as well as it is possible to prevent heat loss to an outside. As a result, a temperature difference between the low temperature portion and the high temperature portion of the thermoelectric module 20 may be sufficiently secured.

Further, the insulation 45 may be filled to surround the thermoelectric module 20, the cooling jacket 30, the pressurizing mat 41, the pressurizing plate 42, or the like within the heat protect cover 50 as well as around the thermoelectric module 20.

As described above, according to the exemplary embodiments of the present invention, since the flat surface is formed on a top surface of the manifold body, the cross section of the manifold body may be formed to be greater than that of the inlet portion, making it possible to improve the fluidity of the exhaust gas and to improve the fuel efficiency of the vehicle by the improvement of the fluidity of the exhaust gas.

Further, since the flat surface is formed on at least one surface of the manifold body, the exhaust heat collection mechanism such as the thermoelectric module, or the like may be very firmly and stably mounted onto the manifold body, thereby making it possible to improve collection efficiency of the exhaust heat using the thermoelectric module, or the like.

The foregoing descriptions of specific exemplary embodiments of the present invention have been presented for purposes of illustration and description. They are not intended to be exhaustive or to limit the invention to the precise forms disclosed, and obviously many modifications and variations are possible in light of the above teachings. The exemplary embodiments were chosen and described in order to explain certain principles of the invention and their practical application, to thereby enable others skilled in the art to make and utilize various exemplary embodiments of the present invention, as well as various alternatives and modifications thereof. It is intended that the scope of the invention be defined by the Claims appended hereto and their equivalents.

What is claimed is:

1. An exhaust manifold comprising:
a manifold body configured to have a plurality of inlet portions which are outwardly extended and an outlet portion which is outwardly extended,
wherein the manifold body has a flat surface formed on at least a portion of a top surface thereof.

2. The exhaust manifold according to claim 1, wherein at least one stud protrudes from the flat surface of the manifold body.

3. The exhaust manifold according to claim 1, wherein an inlet flange is coupled to the plurality of inlet portions, and
the inlet flange has a plurality of openings which are in communication with the plurality of inlet portions.

4. The exhaust manifold according to claim 1, wherein a catalyst converter is connected to the outlet portion.

5. An exhaust manifold comprising:
a manifold body configured to have a flat surface formed on at least a portion of a top surface thereof; and
an exhaust heat collection mechanism configured to be mounted onto the flat surface of the manifold body.

6. The exhaust manifold according to claim 5, wherein the exhaust heat collection mechanism includes at least one thermoelectric module.

7. The exhaust manifold according to claim 5, wherein a stud protrudes from the flat surface of the manifold body.

8. The exhaust manifold according to claim 6, wherein a heat protect cover covering the at least a thermoelectric module is mounted on the manifold body using the stud.

9. The exhaust manifold according to claim 6, wherein a cooling jacket is mounted on the at least a thermoelectric module.

10. The exhaust manifold according to claim 9, further comprising a pressurizing member configured to pressurize the at least a thermoelectric module toward the flat surface of the manifold body.

11. The exhaust manifold according to claim 10, wherein the pressurizing member includes a pressurizing mat mounted on the cooling jacket.

12. The exhaust manifold according to claim 10, wherein the pressurizing member includes a metal mesh having both damping property and pressurizing property.

13. The exhaust manifold according to claim 10, wherein a pressurizing plate pressurizing the pressurizing member is mounted on the pressurizing member.

14. The exhaust manifold according to claim 6, wherein an insulation is filled around the at least a thermoelectric module.
